(19) United States
(12) Patent Application Publication
(10) Pub. No.: US 2013/0161611 A1
(43) Pub. Date: Jun. 27, 2013

(54) SEMICONDUCTOR DEVICE AND METHOD FOR MANUFACTURING THE SAME

(71) Applicant: Semiconductor Energy Laboratory Co., Ltd., Atsugi-shi (JP)

(72) Inventors: Shunpei Yamazaki, Tokyo (JP); Daisuke Matsubayashi, Atsugi (JP); Atsuo Isobe, Isehara (JP)

(73) Assignee: SEMICONDUCTOR ENERGY LABORATORY CO., LTD., Atsugi-shi (JP)

(21) Appl. No.: 13/724,974

(22) Filed: Dec. 21, 2012

(30) Foreign Application Priority Data
Dec. 27, 2011 (JP) 2011-285682

(51) Int. Cl. H01L 29/786; H01L 21/36

(52) U.S. Cl. CPC H01L 29/786; H01L 21/36
USPC 257/43; 438/104

(57) ABSTRACT

Release of oxygen at a side surface of an island-shaped oxide semiconductor film is controlled and decrease in resistance is prevented. A semiconductor device includes an island-shaped oxide semiconductor film at least partly including a crystal, a first gate insulating film provided to cover at least a side surface of the island-shaped oxide semiconductor film, and a second gate insulating film provided to cover at least the island-shaped oxide semiconductor film and the first gate insulating film. The first gate insulating film is an insulating film that supplies oxygen to the island-shaped oxide semiconductor film, and the second gate insulating film is an insulating film which has a low oxygen-transmitting property

### BACKGROUND OF THE INVENTION

1. Field of the Invention

The present invention relates to a semiconductor device and a method for manufacturing the semiconductor device.

2. Description of the Related Art

In recent years, metal oxides having semiconductor characteristics (hereinafter, referred to as oxide semiconductors) have attracted attention. An oxide semiconductor can be applied to a transistor (see Patent Documents 1 and 2).

### REFERENCE

### Patent Document

[Patent Document 1] Japanese Published Patent Application No. 2007-123861
[Patent Document 2] Japanese Published Patent Application No. 2007-096055

### SUMMARY OF THE INVENTION

Oxygen vacancy significantly influences electric characteristics of a transistor which includes an oxide semiconductor. That is, when there are many oxygen vacancies in the oxide semiconductor film, conductivity becomes high, so that it becomes difficult to reduce off-state current sufficiently, and switching characteristics may be degraded. Therefore, the oxide semiconductor film needs sufficient oxygen and preferably contains excessive oxygen.

The oxide semiconductor film can be in a single crystal state, a polycrystalline (also referred to as polycrystal) state, an amorphous state, or the like. In one embodiment, the oxide semiconductor film includes a crystal at least partly. The oxide semiconductor film according to one embodiment of the present invention is preferably a c-axis aligned crystalline oxide semiconductor (CAAC-OS) film.

The CAAC-OS is not completely single crystal nor completely amorphous. The CAAC-OS is an oxide semiconductor with a crystal-amorphous mixed phase structure where crystal parts and amorphous parts are included in an amorphous phase. Note that in most cases, the crystal part fits inside a cube whose one side is less than 100 nm. From an observation image obtained with a transmission electron microscope (TEM), a boundary between an amorphous part and a crystal part in the CAAC-OS is not clear. Further, with the TEM, a grain boundary in the CAAC-OS is not found. Thus, in the CAAC-OS, a reduction in electron mobility, due to the grain boundary, is suppressed.

In each of the crystal parts included in the CAAC-OS, a c-axis is aligned in a direction parallel to a normal vector of a surface where the CAAC-OS is formed or a normal vector of a surface of the CAAC-OS, triangular or hexagonal atomic arrangement which is seen from the direction perpendicular to the a-b plane is formed, and metal atoms are arranged in a layered manner or metal atoms and oxygen atoms are arranged in a layered manner when seen from the direction perpendicular to the c-axis. Note that, among crystal parts, the directions of the a-axis and the b-axis of one crystal part may be different from those of another crystal part. In this specification, a simple term “perpendicular” includes a range from 85° to 95°. In addition, a simple term “parallel” includes a range from −5° to 5°.

In the CAAC-OS, distribution of crystal parts is not necessarily uniform, and the proportion of crystal parts in the vicinity of the surface of the CAAC-OS may be higher than that in the vicinity of the surface where the CAAC-OS is formed. For example, in the formation of the CAAC-OS, in the case where crystal growth occurs from a surface side of the CAAC-OS, the proportion of crystal parts in the vicinity of the surface of the CAAC-OS is higher than that in the vicinity of the surface where the CAAC-OS is formed in some cases. Further, an additive may be added to the CAAC-OS by doping or the like so that part of the CAAC-OS becomes amorphous.

The c-axes of the crystal parts included in the CAAC-OS are aligned in the direction parallel to a normal vector of the surface where the CAAC-OS is formed or a normal vector of the surface of the CAAC-OS; accordingly, the c-axes directions may be different from each other depending on the shape of the CAAC-OS (the cross-sectional shape of the surface where the CAAC-OS is formed or the cross-sectional shape of the surface of the CAAC-OS). Note that when the CAAC-OS is formed, the direction of c-axis of the crystal part is the direction parallel to a normal vector of the surface where the CAAC-OS is formed or a normal vector of the surface of the CAAC-OS. The crystal part may be formed at the time of formation of the film or may be formed by crystallization treatment (e.g., heat treatment) after the film formation.

With the use of the CAAC-OS, the change in electric characteristics of the transistor due to irradiation with visible light or ultraviolet light can be reduced; thus, the transistor can have high reliability.

Here, as an example of the oxide semiconductor film, ease of excessive oxygen (oxygen atoms in excess of the stoichiometric composition of the oxide semiconductor film) transfer and ease of oxygen vacancy transfer in an In—Ga—Zn-based oxide (hereinafter, referred to as IGZO) film which contains three kinds of metals are described with reference to scientific computation results.

Ease of excessive oxygen transfer and ease of oxygen vacancy transfer are described. In the computation, a model in which one excessive oxygen atom exists in one InO₂ layer of IGZO with crystallinity is formed by structure optimization, and each energy of intermediate structures along a minimum energy path was calculated by a nudged elastic band (NEB) method.

The computation was performed using calculation program software “OpenMX” based on the density functional theory (DFT). Parameters are described below.

As a basis function, a pseudoatom local basis function was used. The basis function is classified into polarization basis sets STO (slater type orbital).

As a functional, generalized-gradient-approximation/Perdew-Burke-Ernzerhof (GGA/PBE) was used.

The cut-off energy was 200 Ry.

The sampling point k was 5×5×3.

In the computation of ease of excessive oxygen transfer, the number of atoms which existed in the computation model was set to 85, and in the computation of ease of oxygen vacancy transfer, the number of atoms which existed in the computation model was set to 83.

Ease of excessive oxygen transfer and ease of oxygen vacancy transfer are evaluated by calculation of a height of energy barrier Eb which is required to go over in moving to respective sites. That is, when the height of energy barrier Eb which is gone over in moving is high, excessive oxygen or oxygen vacancy hardly moves, and when the height of the energy barrier Eb is low, excessive oxygen or oxygen vacancy easily moves.

First, excessive oxygen transfer is described. FIGS. 1A to 1C show models used for computation of excessive oxygen transfer. The computations of two transition forms described below were performed. FIG. 2 shows the computations results. In FIG. 2, the horizontal axis indicates a path length (of excessive oxygen transfer), and the vertical axis indicates relative energy based on energy in a state of a model A in FIG. 1A.

In two transition forms of the excessive oxygen transfer, a first transition is a transition from the model A to a model B shown in FIG. 1B and a second transition is a transition from the model A to a model C shown in FIG. 1C.

In FIGS. 1A to 1C, an oxygen atom denoted by “1” is referred to as a first oxygen atom of the model A; an oxygen atom denoted by “2” is referred to as a second oxygen atom of the model A; and an oxygen atom denoted by “3” is referred to as a third oxygen atom of the model A.

As seen from FIG. 2, the height Eb of the energy barrier in the first transition is 0.53 eV, and that of the second transition is 2.38 eV. That is, the height Eb of the energy barrier in the first transition is lower than that of the second transition. Therefore, energy required for the first transition is smaller than energy required for the second transition, and the first transition occurs more easily than the second transition.

That is, the first oxygen atom of the model A moves in the direction in which the second oxygen atom of the model A is pushed more easily than in the direction in which the third oxygen atom of the model A is pushed. Therefore, this shows that the oxygen atom moves along the InO₂ layer more easily than across the InO₂ layer.

For the above-described computation, models each in which one excessive oxygen atom exists in the InO₂ layer which is one of IGZOs with crystallinity is used and computation results of models different from the models used for the above-described computation are shown below. Specifically, a model in which one excessive oxygen atom exists in the InO₂ layer (see FIG. 10A) and models in which one excessive oxygen atom exists in a layer containing a gallium atom and a zinc atom (see FIGS. 10B, 11A, and 11B) are formed by structure optimization, and each energy of intermediate structures along a minimum energy path was calculated by an NEB method. Note that the computations of these different models were performed similarly to the above-described computation.

FIGS. 10A and 10B show part of models used for computation of excessive oxygen transfer. The computations of two transition forms described below were performed. FIG. 12 shows the computations results. In FIG. 12, the horizontal axis indicates a path length (of excessive oxygen transfer), and the vertical axis indicates relative energy based on energy in a state of a model D in FIG. 10A or a state of a model F in FIG. 11A.

In two transition forms of the excessive oxygen transfer, a third transition is a transition from the model D shown in FIG. 10A to a model E shown in FIG. 10B, specifically, a transition in which the excessive oxygen in the InO₂ layer moves to the layer containing gallium and zinc. A fourth transition is a transition from the model F shown in FIG. 11A to a model G shown in FIG. 11B, specifically, a transition in which the excessive oxygen in the layer containing gallium and zinc moves to an adjacent layer containing gallium and zinc.

In FIGS. 10A and 10B, an oxygen atom denoted by “1” is referred to as a first oxygen atom of the model D and an oxygen atom denoted by “2” is referred to as a second oxygen atom of the model D. In FIGS. 11A and 11B, an oxygen atom denoted by “1” is referred to as a first oxygen atom of the model F and an oxygen atom denoted by “2” is referred to as a second oxygen atom of the model F.

As seen from FIG. 12, the height Eb of the energy barrier of the third transition is 0.61 eV, and that of the fourth transition is 0.29 eV. That is, the height Eb of the energy barrier of the third transition is higher than that of the fourth transition. Therefore, energy required for the fourth transition is smaller than energy required for the third transition, and the fourth transition occurs more easily than the third transition.

That is, transfer of excessive oxygen from the layer containing a gallium atom and a zinc atom to the layer containing a gallium atom and a zinc atom, which is adjacent to the layer, occurs more easily than transfer of excessive oxygen from the InO₂ layer to the layer containing a gallium atom and a zinc atom.

Further, FIG. 2 and FIG. 12 show that excessive oxygen moves easily in order of increasing height Eb of the energy barrier. That is, excessive oxygen moves easily in order of the fourth transition, the first transition, the third transition, and the second transition.

Next, oxygen vacancy transfer is described. FIGS. 3A to 3C show models used for computation of oxygen vacancy transfer. The computations of two transition forms described below were performed. FIG. 4 shows the computations results. In FIG. 4, the horizontal axis indicates a path length (of oxygen vacancy transfer), and the vertical axis indicates relative energy based on energy in a state of a model A in FIG. 3A.

In two transition forms of the oxygen vacancy transfer, a first transition is a transition from the model A to a model B shown in FIG. 3B and a second transition is a transition from the model A to a model C shown in FIG. 3 C.

Note that dashed circles in FIGS. 3A to 3C represent oxygen vacancy.

As is seen from FIG. 4, the height Eb of the energy barrier of the first transition is 1.81 eV, and that of the second transition is 4.10 eV. That is, the height Eb of the energy barrier of the first transition is lower than that of the second transition. Therefore, energy required for the first transition is smaller than energy required for the second transition, and the first transition occurs more easily than the second transition.

That is, the oxygen vacancy of the model A moves to the position of oxygen vacancy of the model B more easily than to the position of oxygen vacancy of the model C. Therefore, this shows that the oxygen vacancy also moves along the InO₂ layer more easily than across the InO₂ layer.

Next, in order to compare probabilities of occurrence of the above-described six transition forms from another side, temperature dependence of these transitions is described. The above-described six transition forms are (1) the first transition of excessive oxygen, (2) the second transition of excessive oxygen, (3) the third transition of excessive oxygen, (4) the fourth transition of excessive oxygen, (5) the first transition of oxygen vacancy, and (6) the second transition of oxygen vacancy.

Temperature dependence of these transitions is compared with each other based on movement frequency per unit time. Here, movement frequency Z (per second) at certain temperature T (K) is represented by the following formula (1) when the number of vibrations Zo (per second) of an oxygen atom in the chemically stable position is used.

$$\begin{matrix}[ FORMULA 1 ] & \\ Z = Z o \cdot exp ( - \frac{Eb}{kT} ) & ( 1 )\end{matrix}$$

Note that in the formula (1), Eb represents a height of an energy barrier of each transition, and k represents a Boltzmann constant. Further, Zo=1.0×10¹³ (per second) is used for the calculation.

In the case where excessive oxygen or oxygen vacancy moves beyond the height of the energy barrier Eb once per one second (in the case of Z=1 (per second)), when the formula (1) is solved for T, the following formulas are obtained.

In the first transition of excessive oxygen of Z=1, T=206 K (−67° C.). (1)

In the second transition of excessive oxygen of Z=1, T=923 K (650° C.). (2)

In the third transition of excessive oxygen of Z=1, T=240 K (−33° C.). (3)

In the fourth transition of excessive oxygen of Z=1, T=113 K (−160° C.). (4)

In the first transition of oxygen vacancy of Z=1, T=701 K (428° C.). (5)

In the second transition of oxygen vacancy of Z=1, T=1590 K (1317° C.). (6)

On the other hand, Z in the case of T=300 K (27° C.) is represented by the following formulas.

In the first transition of excessive oxygen of T=300 K, Z=1.2×10⁴ (per second). (1)

In the second transition of excessive oxygen of T=300 K, Z=1.0×10⁻²⁷ (per second). (2)

In the third transition of excessive oxygen of T=300 K, Z=3.9×10² (per second). (3)

In the fourth transition of excessive oxygen of T=300 K, Z=1.2×10⁸ (per second). (4)

In the first transition of oxygen vacancy of T=300 K, Z=4.3×10⁻¹⁸ (per second). (5)

In the second transition of oxygen vacancy of T=300 K, Z=1.4×10⁻⁵⁶ (per second). (6)

Further, Z in the case of T=723 K (450° C.) is represented by the following formulas.

In the first transition of excessive oxygen of T=723 K, Z=2.0×10⁹ (per second). (1)

In the second transition of excessive oxygen of T=723 K, Z=2.5×10⁻⁴ (per second). (2)

In the third transition of excessive oxygen of T=723 K, Z=4.8×10⁸ (per second). (3)

In the fourth transition of excessive oxygen of T=723 K, Z=9.2×10¹⁰ (per second). (4)

In the first transition of excessive oxygen of T=723 K, Z=2.5 (per second). (5)

In the second transition of excessive oxygen of T=723 K, Z=2.5×10⁻¹⁶ (per second) (6)

In view of the above-described calculation, excessive oxygen, in the case of either T=300 K or T=723 K, moves along the InO₂ layer more easily than across the InO₂ layer. Moreover, oxygen vacancy also, in the case where either T=300 K or T=723 K, moves along the InO₂ layer more easily than across the InO₂ layer.

Further, in the case of either T=300 K or T=723 K, it can be said that a transition form in which excessive oxygen moves most easily is the fourth transition of excessive oxygen, in which excessive oxygen which existed in the layer containing a gallium atom and a zinc atom moves to an adjacent layer containing a gallium atom and a zinc atom. That is, it can be said that excessive oxygen easily moves in a parallel direction to a surface where a film is formed or a surface of the film.

Further, in the case of T=300 K, the movement of the excessive oxygen along the InO₂ layer occurs extremely easily; however, the other transitions do not occur easily. In the case of T=723 K, not only the movement of the excessive oxygen along the InO₂ layer but the movement of the oxygen vacancy along the InO₂ layer occurs easily; however, it is difficult for either the excessive oxygen or the oxygen vacancy to move across the InO₂ layer.

As described above, in the CAAC-OS, excessive oxygen and oxygen vacancy easily move in a parallel direction to a surface where a film is formed or a surface of the film. Therefore, there is a problem about release of oxygen from a side surface of the film. When oxygen is released, excessive oxygen is decreased, so that it is difficult to fill oxygen vacancy. If there is oxygen vacancy, the conductivity of the CAAC-OS might be high up to a level at which the CAAC-OS is not preferable used for a switching element.

Note that the case where the excessive oxygen or the oxygen vacancy moves across the InO₂ layer is described above; however, the present invention is not limited thereto, and the same applies to layers of metals other than indium which are contained in an oxide semiconductor film.

The above release of oxygen is particularly remarkable in the case where the CAAC-OS is processed into an island shape. This is because an area of a side surface of the oxide semiconductor film increases in the case where an oxide semiconductor film is processed into an island shape.

An object of one embodiment of the present invention is to prevent release of an oxygen atom from a side surface of a CAAC-OS and make the CAAC-OS contain sufficient oxygen. Further, another object is to prevent deterioration of a semiconductor device.

One embodiment of the present invention is a semiconductor device including an island-shaped oxide semiconductor film at least partly including a crystal, a first gate insulating film provided to cover at least a side surface of the island-shaped oxide semiconductor film, and a second gate insulating film provided to cover at least the island-shaped oxide semiconductor film and the first gate insulating film. The first gate insulating film is an insulating film which transmits oxygen supplied to the island-shaped oxide semiconductor film and the second gate insulating film is an insulating film which has a low oxygen-transmitting property.

Another embodiment of the present invention is a semiconductor device including an island-shaped oxide semiconductor film at least partly including a crystal, a first gate insulating film provided to cover at least a side surface of the island-shaped oxide semiconductor film, a second gate insulating film provided to cover at least the island-shaped oxide semiconductor film and the first gate insulating film, and a gate electrode provided over the second gate insulating film to overlap with island-shaped oxide semiconductor film. The first gate insulating film is an insulating film which transmits oxygen supplied to the island-shaped oxide semiconductor film, the second gate insulating film is an insulating film which has a low oxygen-transmitting property, and the gate electrode is provided in contact with the second gate insulating film overlapping with the side surface of the island-shaped oxide semiconductor film.

In any of the above structures, any one or a plurality of metals contained in the island-shaped oxide semiconductor film may be arranged in a layered manner in the island-shaped oxide semiconductor film, and the metal layer may be parallel to a surface where the oxide semiconductor film is formed.

In any of the above structures, as the metal, for example, indium can be exemplified.

In any of the above structures, as the second gate insulating film, an aluminum oxide film can be exemplified.

Another embodiment of the present invention is a method for manufacturing a semiconductor device including a gate insulating film over a first and second oxide semiconductor films, which includes the steps of stacking the first oxide semiconductor film having a low proportion of indium and high proportions of gallium and zinc with the second oxide semiconductor film having high proportions of indium and zinc, and performing heat treatment before the gate insulating film is formed.

Another embodiment of the present invention is a method for manufacturing a semiconductor device including a gate insulating film over a first and second oxide semiconductor films, which includes the steps of stacking the first oxide semiconductor film with the second oxide semiconductor film having higher proportions of indium and zinc and a lower proportion of gallium than the first oxide semiconductor film, and performing heat treatment before the gate insulating film is formed.

In any of the above-described structures, the heat treatment may be performed at a substrate temperature of 400° C. to 800° C. inclusive.

In any of the above-described structure, the gate insulating film has a layered structure of two layers, and an upper layer of the gate insulating film is an aluminum oxide film.

According to one embodiment of the present invention, release of an oxygen atom from a side surface of an oxide semiconductor film can be prevented and the CAAC-OS can contain sufficient oxygen. Further, deterioration of the semiconductor device can be controlled.

### BRIEF DESCRIPTION OF THE DRAWINGS

In the accompanying drawings:

FIGS. 1A to 1C are model diagrams used for calculation of excessive oxygen transfer;

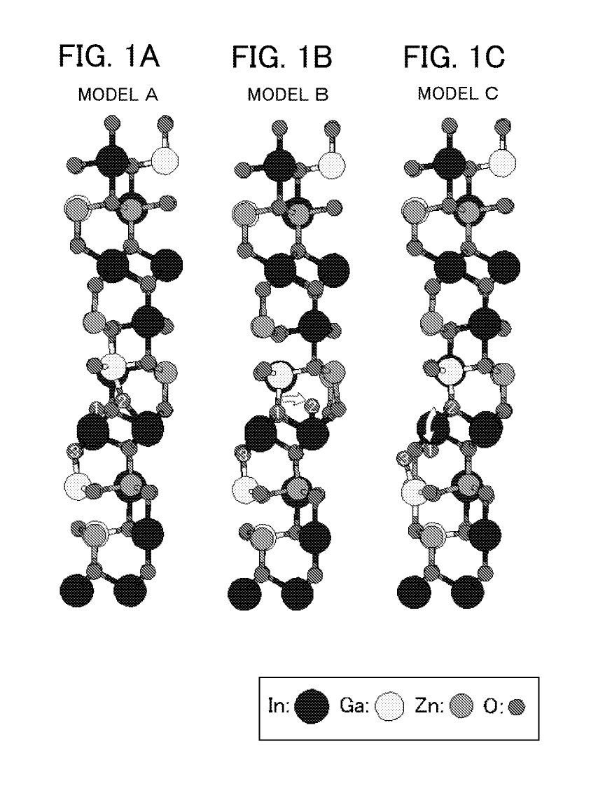

FIG. 2 shows calculation results of excessive oxygen transfer shown in the model diagrams illustrated in FIGS. 1A to 1C;

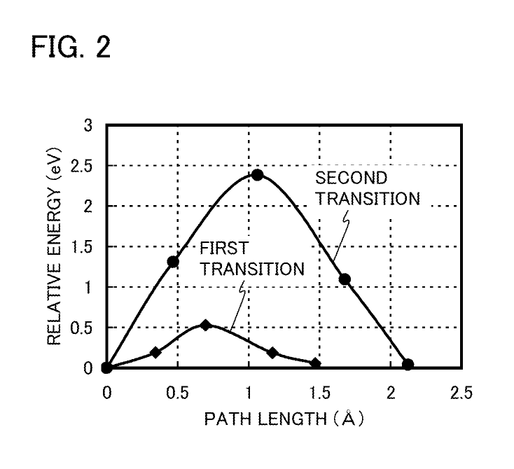

FIGS. 3A to 3C are model diagrams used for calculation of oxygen vacancy transfer;

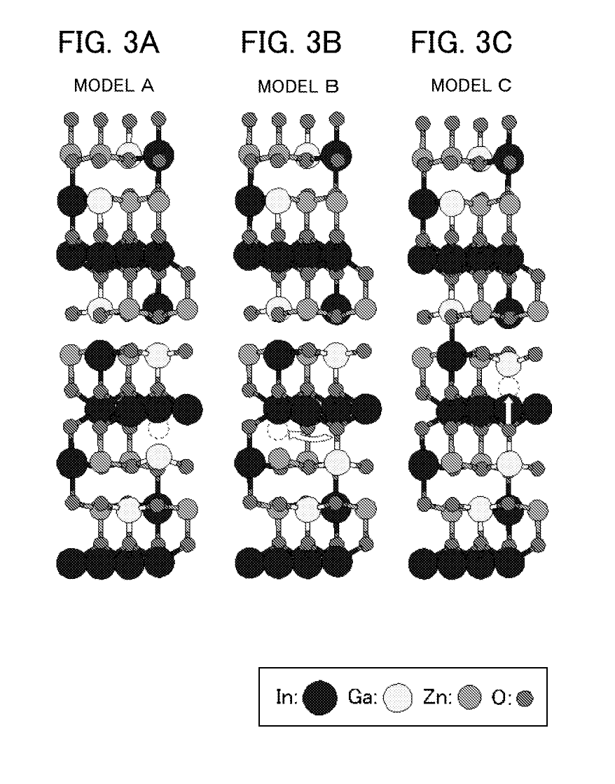

FIG. 4 shows calculation results of excessive oxygen transfer shown in the model diagrams illustrated in FIGS. 3A to 3C;

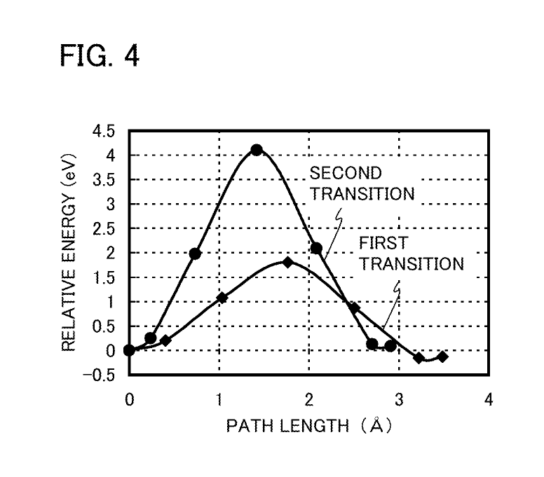

FIGS. 5A to 5C illustrate a semiconductor device that is one embodiment of the present invention;

FIGS. 6A to 6D illustrate a method for manufacturing the semiconductor device that is one embodiment of the present invention;

FIGS. 7A to 7D illustrate a method for manufacturing the semiconductor device that is one embodiment of the present invention;

FIGS. 8A to 8D illustrate a method for manufacturing the semiconductor device that is one embodiment of the present invention;

FIGS. 9A and 9B illustrate an electronic device to which the semiconductor device that is one embodiment of the present invention is applied;

FIGS. 10A and 10B are model diagrams used for calculation of excessive oxygen transfer;

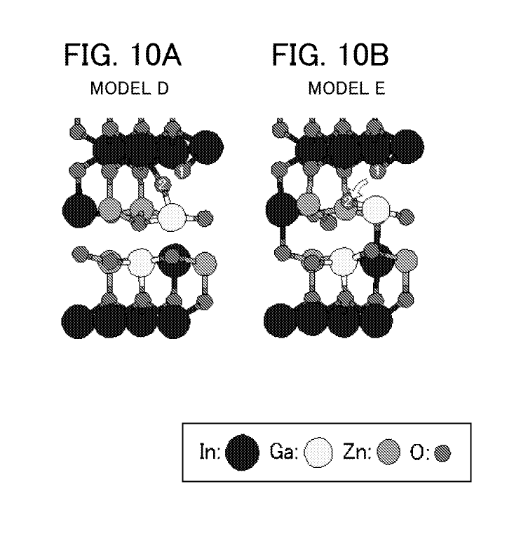

FIGS. 11A and 11B are model diagrams used for calculation of excessive oxygen transfer; and

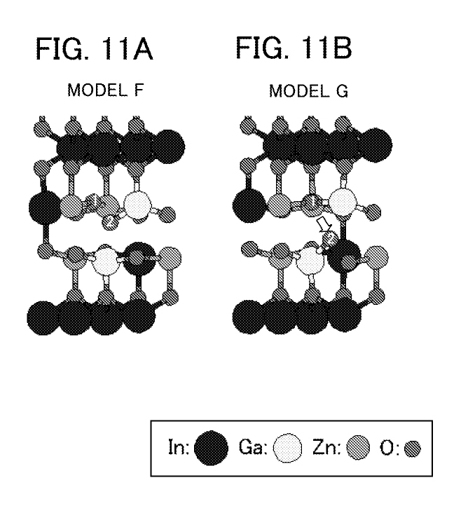

FIG. 12 shows calculation results of excessive oxygen transfer shown in the model diagrams illustrated in FIGS. 10A and 10B and FIGS. 11A and 11B.

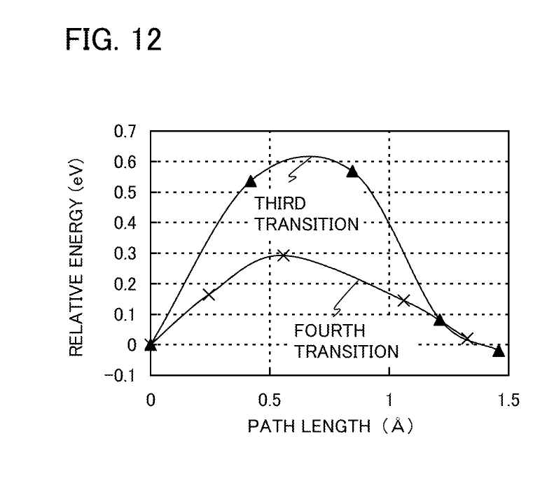

### DETAILED DESCRIPTION OF THE INVENTION

Hereinafter, embodiments of the present invention are described in detail with reference to the accompanying drawings. However, the present invention is not limited to the following description and it is easily understood by those skilled in the art that the mode and details can be variously changed without departing from the scope and spirit of the present invention. Accordingly, the invention should not be construed as being limited to the description of the embodiments below.

### Embodiment 1

In this embodiment, a semiconductor device (transistor) that is one embodiment of the present invention and a manufacturing method thereof are described.

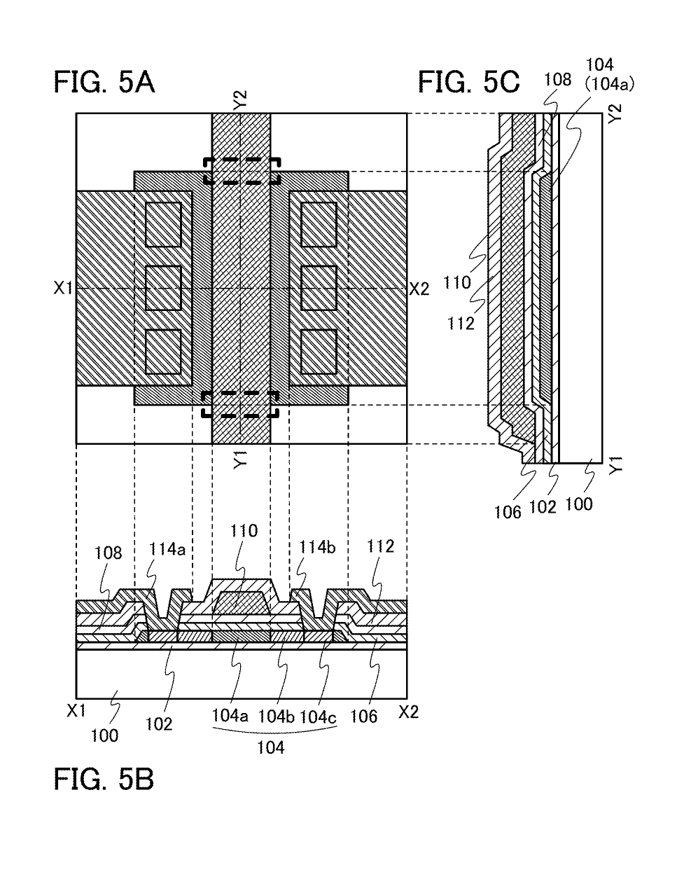

FIGS. 5A to 5C illustrate a transistor as a semiconductor device which is an embodiment of the present invention. FIG. 5A is a top view of the transistor. FIG. 5B is a cross-sectional view taken along the line X1-X2 in FIG. 5A, and FIG. 5C is a cross-sectional view taken along the line Y1-Y2 in FIG. 5A.

The transistor illustrated in FIGS. 5A to 5C includes a base film 102 provided over a substrate 100, an island-shaped oxide semiconductor film 104 provided over the base film 102, a first gate insulating film 106 provided to cover the island-shaped oxide semiconductor film 104, a second gate insulating film 108 provided over the first gate insulating film 106, a gate electrode 110 provided over the second gate insulating film 108, an interlayer insulating film 112 provided to cover the gate electrode 110, and a source electrode 114a and a drain electrode 114b provided over the interlayer insulating film 112 and connected to the island-shaped oxide semiconductor film 104.

In the transistor illustrated in FIGS. 5A to 5C, the first gate insulating film 106 and the second gate insulating film 108 are provided to cover the island-shaped oxide semiconductor film 104. One feature is that the first gate insulating film 106 has a high oxygen-transmitting property and may be provided in contact with the island-shaped oxide semiconductor film 104, and the second gate insulating film 108 has a low oxygen-transmitting property. The first gate insulating film 106 is preferably an oxidizing insulating film which functions as a supply source which supplies oxygen to the island-shaped oxide semiconductor film 104, and the first gate insulating film 106 more preferably contains more proportion of oxygen than proportion of oxygen in the stoichiometry.

As described above, a gate insulating film covering the island-shaped oxide semiconductor film 104 has two layers and the above features, whereby oxygen is supplied sufficiently to the island-shaped oxide semiconductor film 104. The island-shaped oxide semiconductor film 104 contains sufficient oxygen, whereby increase in conductivity by release of oxygen can be prevented.

In particular, in portions indicated by thick dashed lines in FIG. 5A, when conductivity becomes high, a parasitic channel is generated, which causes degradation of switching characteristics and signal delay; however, according to the present invention, decrease in the resistance of the portions indicated by thick dotted lines can be suppressed, so that generation of a parasitic channel, and further, degradation of switching characteristics and signal delay can be prevented.

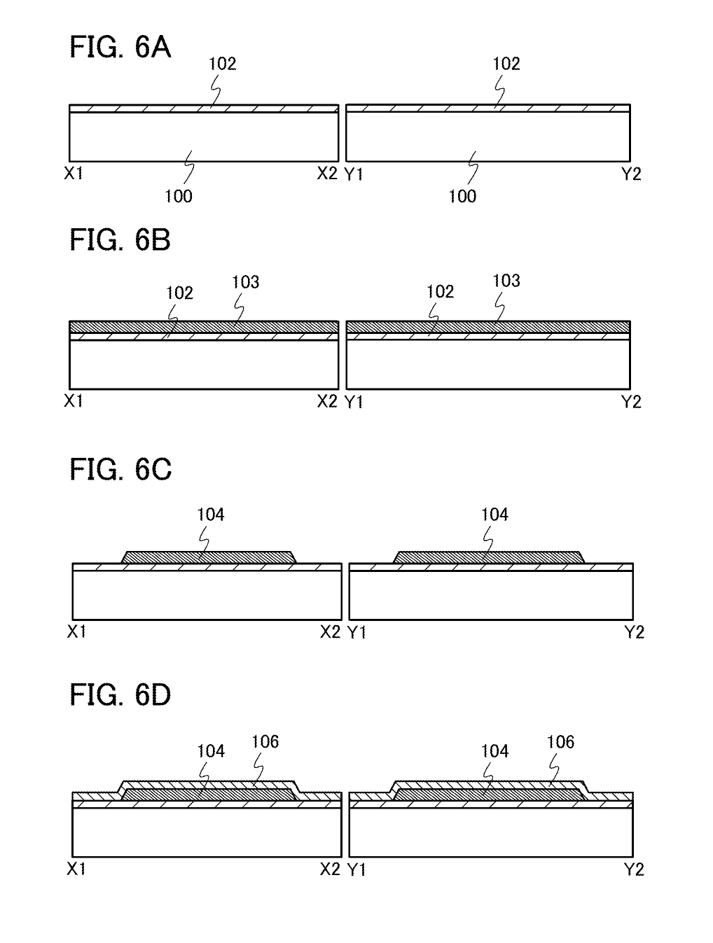

Next, a method for manufacturing a transistor in FIGS. 5A to 5C is described with reference to FIGS. 6A to 6D, FIGS. 7A to 7D, and FIGS. 8A to 8D. The left side of each drawing corresponds to FIG. 5B and the right side thereof corresponds to FIG. 5C.

First, the base film 102 is formed over the substrate 100 (FIG. 6A). The base film 102 may be formed by a sputtering method, a CVD method, or the like, and preferably formed by a method in which hydrogen, water, a hydroxyl group, hydride, and the like do not easily enter.

The substrate 100 is not particularly limited as long as the substrate does not change in quality by heat treatment or the like in a manufacturing step of a transistor.

As the substrate 100, a glass substrate (preferably a non-alkali glass substrate), a quartz substrate, a ceramic substrate, a plastic substrate, a silicon substrate, or the like can be exemplified.

The base film 102 is formed using an insulating material. The base film 102 is in contact with an oxide semiconductor film; therefore, the film preferably includes hydrogen, water, a hydroxyl group, and hydride as little as possible and includes oxygen. More preferably, the base film 102 is formed using an insulating oxide material in which part of oxygen is desorbed by heat treatment.

In particular, the base film 102 preferably contains more proportion of oxygen than proportion of oxygen in the stoichiometry. When the base film 102 contains more proportion of oxygen than proportion of oxygen in the stoichiometry, the base film 102 can function as a supply source which supplies oxygen to the oxide semiconductor film.

As an example of the case where the base film 102 contains more proportion of oxygen than proportion of oxygen in the stoichiometry, the case where x>2 in silicon oxide, SiOx, can be given. However, there is no limitation thereto, and the base film 102 may be formed using silicon oxide, silicon oxynitride, silicon nitride oxide, aluminum oxide, aluminum oxynitride, gallium oxide, hafnium oxide, yttrium oxide, or the like. Note that “silicon nitride oxide” contains more nitrogen than oxygen and “silicon oxynitride” contains more oxygen than nitrogen.

Note that the base film 102 may be a stacked-layer film of two layers in which a plurality of films is stacked. In this case, it is preferable that a barrier film which prevents entry of impurities included in the substrate 100 to the oxide semiconductor film be provided as a lower layer, and an insulating film which functions as a supply source which supplies oxygen to the oxide semiconductor film be provided as an upper layer. As the barrier film, a silicon nitride film or an aluminum oxide film can be exemplified.

After the base film 102 is formed, it is preferable that heat treatment be performed so that hydrogen, water, a hydroxyl group, and hydride are removed (referred to as dehydration or dehydrogenation), and then, oxygen be added by an ion implantation method or the like.

Next, the oxide semiconductor film 103 is formed over the base film 102 (FIG. 6B). After that, the oxide semiconductor film 103 is processed to form the island-shaped oxide semiconductor film 104 (FIG. 6C). The oxide semiconductor film 103 may be formed by a method in which hydrogen, water, a hydroxyl group, hydride, and the like do not easily enter, and is preferably formed by a sputtering method, for example.

The sputtering method may be performed in a rare gas atmosphere, an oxygen atmosphere, or a mixed gas atmosphere of a rare gas and oxygen. Moreover, it is preferable to use a high-purity gas from which hydrogen, water, a hydroxyl group, a hydride, and the like are sufficiently removed so that the entry of hydrogen, water, a hydroxyl group, a hydride, and the like into the oxide semiconductor layer can be prevented.

As a material of the oxide semiconductor film 103, for example, the following can be used: indium oxide, tin oxide, zinc oxide, an oxide containing two kinds of metal, such as an In—Zn-based oxide, a Sn—Zn-based oxide, an Al—Zn-based oxide, a Zn—Mg-based oxide, a Sn—Mg-based oxide, an In—Mg-based oxide, or an In—Ga-based oxide, an oxide containing three kinds of metal, such as an In—Ga—Zn-based oxide (as described above, also referred to as IGZO), an In—Al—Zn-based oxide, an In—Sn—Zn-based oxide, a Sn—Ga—Zn-based oxide, an Al—Ga—Zn-based oxide, a Sn—Al—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide, or an oxide containing four kinds of metal, such as an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, or an In—Hf—Al—Zn-based oxide.

Note that here, for example, an In—Ga—Zn-based oxide means an oxide containing In, Ga, and Zn, and there is no limitation on the composition ratio of In, Ga, and Zn. Further, the In—Ga—Zn-based oxide semiconductor may contain a metal element other than In, Ga, and Zn.

For example, an In—Ga—Zn-based oxide with an atomic ratio of In:Ga:Zn=1:1:1 (=⅓:⅓:⅓) or In:Ga:Zn=2:2:1 (=⅖:⅖:⅕), or an oxide with an atomic ratio close to the above atomic ratios can be used. Alternatively, an In—Sn—Zn-based oxide with an atomic ratio of In:Sn:Zn=1:1:1 (=⅓:⅓:⅓), In:Sn:Zn=2:1:3 (=⅓:⅙:½), or In:Sn:Zn=2:1:5 (=¼:⅛:⅝), or an oxide with an atomic ratio close to the above atomic ratios may be used. However, the materials are not limited thereto.

As described above, the oxide semiconductor film 103 preferably includes a CAAC-OS.

Note that the island-shaped oxide semiconductor film 104 may be a layered structure of two layers. In the case where the island-shaped oxide semiconductor film 104 is, for example, formed using In—Ga—Zn-based oxide, it is preferable that the proportion of gallium and zinc be high and the proportion of indium be low in a layer (a lower layer) which is in contact with the base film 102, and the proportion of zinc and indium be high in a layer (an upper layer) which is not in contact with the base film 102. That is, in the layer (the upper layer) which is not in contact with the base film 102, it is preferable that the proportion of indium and zinc be higher and the proportion of gallium be lower than the layer (the lower layer) which is in contact with the base film 102. In this manner, the proportion of zinc is higher, whereby the CAAC-OS can be preferably formed.

However, when the island-shaped oxide semiconductor film 104 contains a high proportion of zinc, the withstand voltage of a gate insulating film to be formed later tends to be decreased. Therefore, after the CAAC-OS is formed, heat treatment for reducing zinc is preferably performed before the gate insulating film is formed. The heat treatment may be performed at a substrate temperature of 400° C. to 800° C. inclusive, preferably performed at a substrate temperature of about 650° C. When the heat treatment is performed at such a temperature, entry of zinc into the gate insulating film can be prevented and the withstand voltage of the gate insulating film can be improved.

Note that the heat treatment is the step at the highest temperature of manufacturing steps described in this embodiment, and heat treatments performed later are preferably performed at a temperature lower than or equal to a temperature of the heat treatment. This is because the entry of remaining zinc into the gate insulating film is prevented.

Next, the first gate insulating film 106 is formed to cover the island-shaped oxide semiconductor film 104 (FIG. 6D). The first gate insulating film 106 may be formed by a sputtering method, a CVD method, or the like, and the first gate insulating film 106 is preferably formed by a method with which hydrogen, water, a hydroxyl group, hydride, and the like do not easily enter.

The first gate insulating film 106 is an insulating film having a high oxygen-transmitting property, which may be provided in contact with the island-shaped oxide semiconductor film 104. The first gate insulating film 106 is preferably an oxidizing insulating film which functions as a supply source which supplies oxygen to the island-shaped oxide semiconductor film 104, and the first gate insulating film 106 more preferably contains more proportion of oxygen than proportion of oxygen in the stoichiometry.

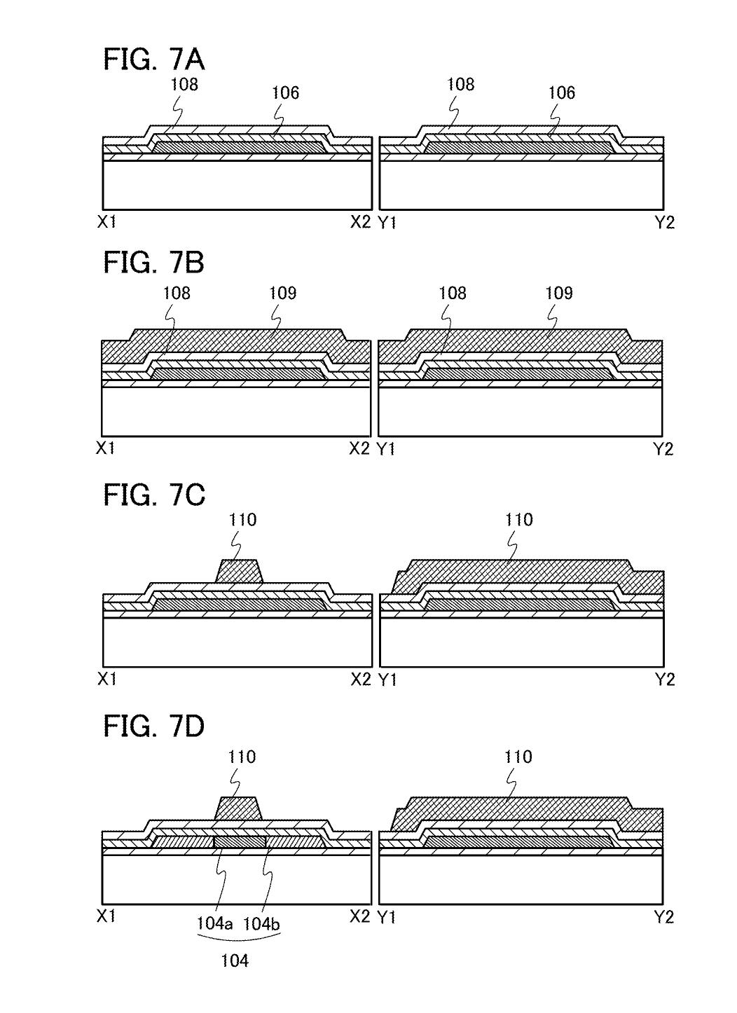

Next, the second gate insulating film 108 is formed over the first gate insulating film 106 (FIG. 7A). The second gate insulating film 108 may be formed by a sputtering method, a CVD method, or the like, and the second gate insulating film 108 is preferably formed by a method with which hydrogen, water, a hydroxyl group, hydride, and the like do not easily enter.

The second gate insulating film 108 may be an insulating film having a low oxygen-transmitting property, which does not release oxygen atom from the island-shaped oxide semiconductor film 104 and the first gate insulating film 106. As such an insulating film having a low oxygen-transmitting property, an aluminum oxide film or a silicon nitride film can be exemplified.

In the case where the second gate insulating film 108 is formed using an aluminum oxide, an aluminum film may be formed first, and an aluminum oxide film may be formed by adding oxygen to the aluminum film. Oxygen may be added, for example, by an ion doping method or an ion implantation method. At this time, oxygen is preferably added after hydrogen, water, a hydroxyl group, hydride, and the like are removed from the first gate insulating film 106 by heat treatment. Note that the aluminum oxide may be formed by a sputtering method.

Then, heat treatment is preferably performed after the second gate insulating film 108 is formed. When the heat treatment is performed after the second gate insulating film 108 is formed, at least one of the base film 102 and the first gate insulating film 106 functions as a supply source of oxygen, and the second gate insulating film 108 having a low oxygen-transmitting property can supply the oxygen to the island-shaped oxide semiconductor film 104 while preventing release of oxygen to the outside, so that oxygen vacancy included in the island-shaped oxide semiconductor film 104 can be filled efficiently. Therefore, a transistor which has favorable electric characteristics can be manufactured.

Heat treatment may be performed after the first gate insulating film 106 is formed. In particular, in the case where the first gate insulating film 106 is formed by a CVD method, by performing heat treatment after the formation, hydrogen, water, a hydroxyl group, hydride, and the like can be removed. Note that this heat treatment is performed at a temperature lower than or equal to that of the heat treatment for removing zinc.

However, the heat treatment for removing hydrogen, water, a hydroxyl group, hydride, and the like causes release of oxygen. Thus, in the case where the heat treatment for removing hydrogen, water, a hydroxyl group, hydride, and the like included in the first gate insulating film 106 is performed, oxygen is preferably added to the first gate insulating film 106 after the heat treatment. Oxygen is added, for example, by an ion doping method or an ion implantation method.

Next, a first conductive film 109 is formed over the second gate insulating film 108 (FIG. 7B). The first conductive film 109 may be formed by a sputtering method, a CVD method, or the like.

The first conductive film 109 may be formed using a conductive material. Examples of the conductive material which can be used for the first conductive film 109 are metal materials such as aluminum, copper, titanium, tantalum, and tungsten, and polycrystalline silicon to which an impurity element imparting conductivity is added.

Next, the first conductive film 109 is processed to form the gate electrode 110 (FIG. 7C). The process is performed by an etching or the like.

Next, a dopant is added to the island-shaped oxide semiconductor film 104 with the use of the gate electrode as a mask, whereby a channel formation region 104a and a region 104b containing the dopant are formed in the island-shaped oxide semiconductor film 104 (FIG. 7D). As the dopant, boron, nitrogen, fluorine, aluminum, phosphorus, arsenic, indium, tin, antimony, helium, neon, argon, krypton, xenon, and the like are exemplified. The dopant may be added, for example, by an ion doping method or an ion implantation method. Then, heat treatment may be performed after the dopant is added. The heat treatment can be performed at the substrate temperature of 300° C. to 500° C. inclusive. The region 104b containing the dopant has a lower resistance than the channel formation region 104a.

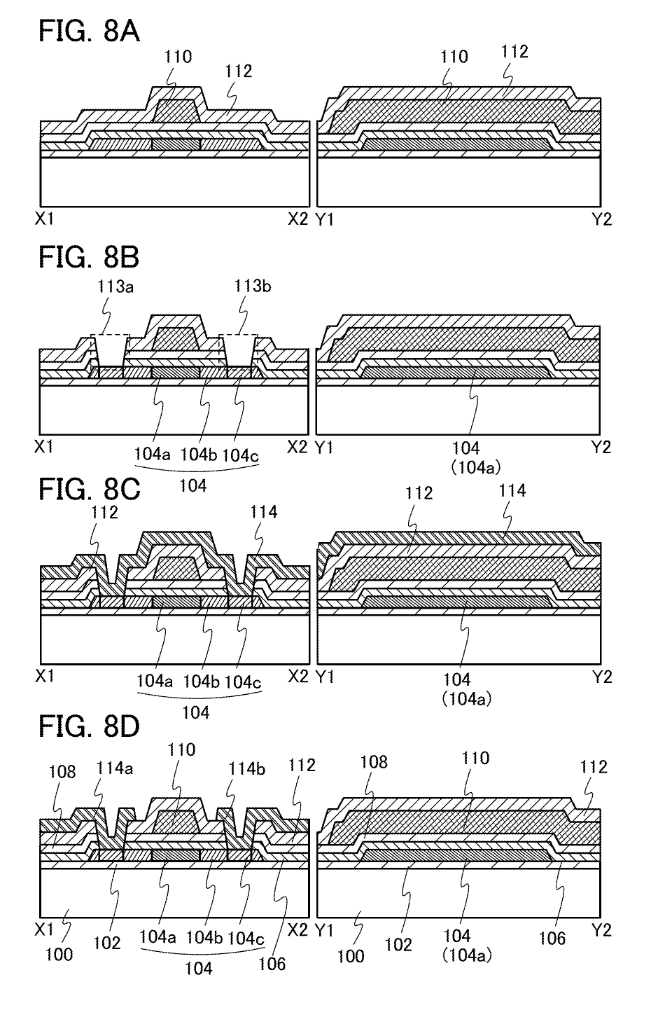

Next, the interlayer insulating film 112 is formed to cover the gate electrode 110 (FIG. 8A). The interlayer insulating film 112 may be formed by a sputtering method, a CVD method, or the like.

The interlayer insulating film 112 may be formed using a material given as an example of the materials of the base film 102, the first gate insulating film 106, and the second gate insulating film 108.

Next, an opening 113a and an opening 113b are formed in the first gate insulating film 106, the second gate insulating film 108, and the interlayer insulating film 112 (FIG. 8B). The opening 113a and the opening 113b are formed by a processing using etching or the like.

Note that it is preferable that a dopant be added to the island-shaped oxide semiconductor film 104 after the openings 113a and 113b are formed, whereby a region 104c containing a dopant be formed in the island-shaped oxide semiconductor film 104 (FIG. 8B). The dopant may be added, for example, by an ion doping method or an ion implantation method. Then, heat treatment may be performed after the dopant is added. The heat treatment can be performed at a substrate temperature of 300° C. to 500° C. inclusive. The region 104c containing the dopant has a lower resistance than the channel formation region 104a and the region 104b containing the dopant.

Next, the second conductive film 114 is formed over the interlayer insulating film 112 (FIG. 8C). The second conductive film 114 is formed to be connected to the island-shaped oxide semiconductor film 104 in the openings 113a and 113b. The second conductive film 114 may be formed by a sputtering method, a CVD method, or the like.

The second conductive film 114 may be formed using a conductive material, and the material given as an example of the material of the first conductive film 109 may be used.

Next, the second conductive film 114 is processed to form the source electrode 114a and the drain electrode 114b (FIG. 8D).

As described above, the transistor illustrated in FIGS. 5A to 5C can be manufactured in the aforementioned manner.

A semiconductor device that is one embodiment of the present invention is not limited to the structure described in this embodiment.

### Embodiment 2

The semiconductor device described in Embodiment 1 which is one embodiment of the present invention can be provided in electronic devices. In this embodiment, an electronic device including the transistor described in Embodiment 1 is described.

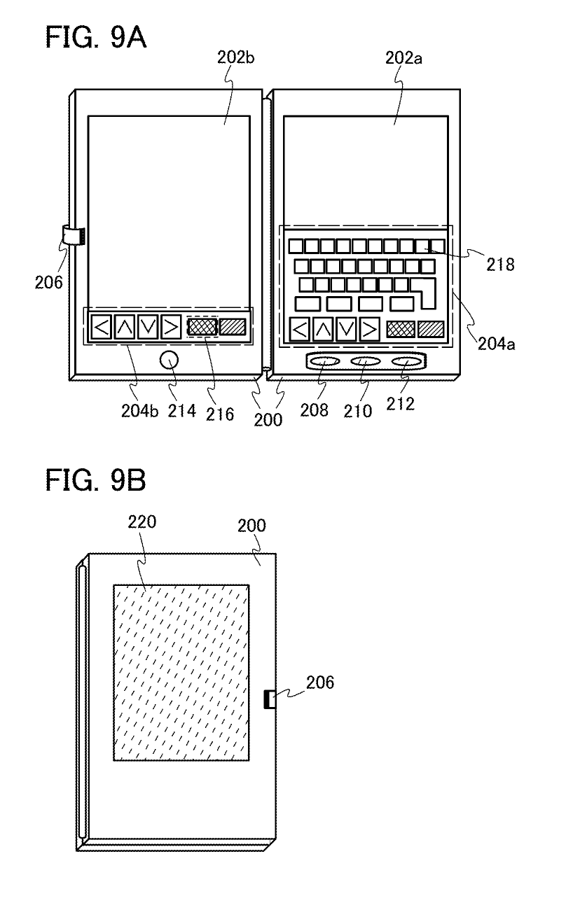

FIGS. 9A and 9B illustrate a tablet terminal that can be folded. FIG. 9A illustrates the tablet terminal opened, and FIG. 9B illustrates the tablet terminal folded. The tablet terminal illustrated in FIG. 9A includes a housing 200, a display portion 202a, a display portion 202b, a clip 206, a display-mode switching button 208, a power button 210, a power-saving-mode switching button 212, and an operation button 214.

The semiconductor device in Embodiment 1 can be applied to pixel transistors in the display portions 202a and 202b. Alternatively, the semiconductor device in Embodiment 1 may be applied to a memory element of the tablet terminal illustrated in FIGS. 9A and 9B.

Further, part of the display portion 202a can be a touch panel region 204a, and data can be input by touching operation keys 218 that are displayed. Note that FIG. 9A shows, as an example, that half of the display portion 202a has only a display function and the other area has a touch panel function; however, this example does not limit the present invention. All the area of the display portion 202a may have a touch panel function. For example, the display portion 202a may display keyboard buttons in the whole region to be a touch panel, and the display portion 202b may be used as a display screen.

Like the display portion 202a, part of the display portion 202b may be a touch panel region 204b. When a finger, a stylus, or the like touches the place where a button 216 for switching to keyboard display is displayed in the touch panel, keyboard buttons can be displayed on the display portion 202b. Note that the display portion 202b may function as a touch panel.

The display-mode switching button 208 preferably enables switching between a landscape mode and a portrait mode, black-and-white display and color display, and the like.

The tablet terminal illustrated in FIGS. 9A and 9B may include: a sensor detecting the amount of light, such as an optical sensor; a sensor for detecting inclination of the tablet terminal, such as an acceleration sensor; or the like.

The power-saving-mode switching button 212 is used for optimizing the luminance of display in accordance with the amount of external light which is detected with an optical sensor when the tablet terminal is in use.

FIG. 9B illustrates the tablet terminal folded, and the tablet terminal includes a solar battery 220 in the housing 200.

The tablet terminal illustrated in FIGS. 9A and 9B includes the solar battery 220; thus, electric power generated when light is received can be utilized.

Since the tablet terminal illustrated in FIGS. 9A and 9B can be folded, the housing 200 can be closed when the tablet terminal is unused. Thus, the display portions 202a and 202b can be protected, which makes it possible to provide a tablet terminal having high durability and improved reliability for long-term use.

This application is based on Japanese Patent Application serial no. 2011-285682 filed with Japan Patent Office on Dec. 27, 2011, the entire contents of which are hereby incorporated by reference.

What is claimed is:

1. A semiconductor device comprising:
an island-shaped oxide semiconductor film;
a first gate insulating film covering at least side faces of the island-shaped oxide semiconductor film; and
a second gate insulating film covering the island-shaped oxide semiconductor film and the first gate insulating film,
wherein the second gate insulating film has a lower oxygen-transmitting property than that of the first gate insulating film.

2. The semiconductor device according to claim 1,
wherein at least one kind of metal contained in the island-shaped oxide semiconductor film, and
wherein atoms of the metal is arranged in a layered manner parallel to a surface where the island-shaped oxide semiconductor film is formed.

3. The semiconductor device according to claim 2, wherein the metal is indium.

4. The semiconductor device according to claim 1,
wherein the island-shaped oxide semiconductor film has a layered structure of at least two layers, each of a lower layer and an upper layer of the layered structure comprising at least a metal.

5. The semiconductor device according to claim 4, wherein each of the lower layer and the upper layer comprises gallium, zinc, and indium.

6. The semiconductor device according to claim 5,
wherein in the lower layer, each of proportions of gallium and zinc is larger than a proportion of indium, and
wherein in the upper layer, a proportion of gallium is smaller than each of proportions of zinc and indium.

7. The semiconductor device according to claim 5,
wherein a proportion of gallium in the lower layer is larger than a proportion of gallium in the upper layer, and
wherein a proportion of indium in the upper layer is larger than a proportion of indium in the lower layer.

8. The semiconductor device according to claim 1, wherein the second gate insulating film comprises aluminum oxide.

9. The semiconductor device according to claim 1, further comprising a gate electrode being in contact with the second gate insulating film overlapping with the side faces of the island-shaped oxide semiconductor film.

10. A semiconductor device comprising:
an island-shaped oxide semiconductor film;
a first gate insulating film covering at least side faces of the island-shaped oxide semiconductor film; and
a second gate insulating film covering the island-shaped oxide semiconductor film and the first gate insulating film,
wherein the first gate insulating film contains more proportion of oxygen than proportion of oxygen in stoichiometry of the first gate insulating film, and
wherein the second gate insulating film has a lower oxygen-transmitting property than that of the first gate insulating film.

11. The semiconductor device according to claim 10,
wherein at least one kind of metal contained in the island-shaped oxide semiconductor film, and
wherein atoms of the metal is arranged in a layered manner parallel to a surface where the island-shaped oxide semiconductor film is formed.

12. The semiconductor device according to claim 11, wherein the metal is indium.

13. The semiconductor device according to claim 10,
wherein the island-shaped oxide semiconductor film has a layered structure of at least two layers, each of a lower layer and an upper layer of the layered structure comprising at least a metal.

14. The semiconductor device according to claim 13, wherein each of the lower layer and the upper layer comprises gallium, zinc, and indium.

15. The semiconductor device according to claim 14,
wherein in the lower layer, each of proportions of gallium and zinc is larger than a proportion of indium, and
wherein in the upper layer, a proportion of gallium is smaller than each of proportions of zinc and indium.

16. The semiconductor device according to claim 14,
wherein a proportion of gallium in the lower layer is larger than a proportion of gallium in the upper layer, and
wherein a proportion of indium in the upper layer is larger than a proportion of indium in the lower layer.

17. The semiconductor device according to claim 10, wherein the second gate insulating film comprises aluminum oxide.

18. The semiconductor device according to claim 10, further comprising a gate electrode being in contact with the second gate insulating film overlapping with the side faces of the island-shaped oxide semiconductor film.

19. A method for manufacturing a semiconductor device comprising the steps of:
forming a base film over a substrate;
forming an island-shaped oxide semiconductor film on the base film, the island-shaped oxide semiconductor film having a layered structure of at least two layers, wherein each of a lower layer and an upper layer of the layered structure comprises gallium, zinc, and indium,
performing heat treatment; and then
forming a gate insulating film over the island-shaped oxide semiconductor film,
wherein in the lower layer, each of proportions of gallium and zinc is larger than a proportion of indium, and
wherein in the upper layer, a proportion of gallium is smaller than each of proportions of zinc and indium.

20. The method for manufacturing a semiconductor device, according to claim 19, wherein a temperature of the heat treatment is higher than or equal to 400° C. and lower than or equal to 800° C.

21. The method for manufacturing a semiconductor device, according to claim 19,
wherein the gate insulating film has a layered structure of two layers, and
wherein an upper layer of the layered structure of the gate insulating film comprises aluminum oxide.

22. A method for manufacturing a semiconductor device comprising the steps of:
forming a base film over a substrate;
forming an island-shaped oxide semiconductor film on the base film, the island-shaped oxide semiconductor film having a layered structure of at least two layers, wherein each of a lower layer and an upper layer of the layered structure comprises gallium, zinc, and indium,
performing heat treatment; and then
forming a gate insulating film over the island-shaped oxide semiconductor film,
wherein a proportion of gallium in the lower layer is larger than a proportion of gallium in the upper layer, and
wherein a proportion of indium in the upper layer is larger than a proportion of indium in the lower layer.

23. The method for manufacturing a semiconductor device, according to claim 22, wherein a temperature of the heat treatment is higher than or equal to 400° C. and lower than or equal to 800° C.

24. The method for manufacturing a semiconductor device, according to claim 22,
wherein the gate insulating film has a layered structure of two layers, and
wherein an upper layer of the layered structure of the gate insulating film comprises aluminum oxide.
